(19) United States
(12) Patent Application Publication
(10) Pub. No.: US 2021/0305015 A1
(43) Pub. Date: Sep. 30, 2021

(54) SUBSTRATE PROCESSING APPARATUS

(71) Applicant: PSK INC., Hwaseong-si (KR)

(72) Inventors: KWANG-BO SIM, Hwaseong-si (KR); JI-HOON YOON, Hwaseong-si (KR); DONG-WHEE SHIN, Hwaseong-si (KR); HYUN-WOO OH, Hwaseong-si (KR); KA-RAM KANG, Hwaseong-si (KR)

(21) Appl. No.: 17/213,065

(22) Filed: Mar. 25, 2021

(30) Foreign Application Priority Data
Mar. 30, 2020 (KR) 10-2020-0038521

(51) Int. Cl. H01J 37/32; H01L 21/67

(52) U.S. Cl. CPC H01J 37/3244; H01J 2237/334; H01L 21/67069

(57) ABSTRACT

Disclosed herein is an apparatus for processing a substrate. The apparatus comprises: a process processing unit for providing a processing space in which a substrate processing is performed; a plasma generation unit for generating plasma, wherein the plasma generation unit comprises: a plasma chamber having a plasma generation space; a gas supply unit for supplying a processing gas to the plasma generation space; a power application unit for generating plasma by exiting the processing gas in the plasma generation space; a diffusion chamber disposed below the plasma chamber and having a diffusion space for diffusing the plasma generated in the plasma generation space and/or the processing gas supplied to the plasma generation space to be uniformly delivered to the processing space, wherein at least one perforated diffusion plate may be disposed in the diffusion space.

### FIELD OF THE INVENTION

The present disclosure relates to a substrate processing apparatus, more specifically, a substrate processing apparatus treating a substrate using plasma.

A claim for priority under 35 U.S.C. § 119 is made to Korean Patent Application No. 10-2020-0038521 filed on Mar. 30, 2020, in the Korean Intellectual Property Office, the entire contents of which are hereby incorporated by reference.

### BACKGROUND

Plasma refers to an ionized gas composed of ions, electrons, radicals, or the like. Plasma may be generated by using very high temperature heat, strong electric fields or RF electromagnetic fields. A semiconductor device fabrication process includes an ashing process or etching process using plasma to remove a thin film. Ashing or etching are carried out by colliding ions or radical species included in the plasma with a film on a substrate.

FIG. 1. is a view showing a conventional plasma processing apparatus. Referring to FIG. 1, a plasma processing apparatus 2000 comprises a processing unit 2100 and a plasma generation unit 2300.

The processing unit 2100 treats a substrate W using plasma generated in the plasma generation unit 2300. The processing unit 2100 comprises a housing 2110, a support unit 2120 and a baffle 2130. The housing 2110 comprises an internal space 2112 and the support unit 2120 supports the substrate W in the internal space 2112. Multiple holes are formed on the baffle 2130 and the baffle 2130 is provided above the support unit 2120.

The plasma generation unit 2300 generates plasma. The plasma generation unit 2300 comprises a plasma generation chamber 2310, a gas supply unit 2320, a power application unit 2330, and a diffusion chamber 2340. A process G supplied from the gas supply unit 2320 is excited into a plasma state by the high frequency power applied by the power application unit 2330. The generated plasma is supplied to the inner space 2112 through the diffusion chamber 2340. The plasma P and the processing gas supplied to the inner space 2112 are transferred to the substrate W to process the substrate W. Then, the plasma P and/or the processing gas G is discharged to the outside through the hole 2114 formed on the housing 2110.

When the processing of the substrate W continues in the conventional plasma processing apparatus 2000, the temperature of a central zone A of the baffle 2130 increases. Specifically, the plasma P and/or the processing gas G is delivered to the baffle 2130 through the plasma generation chamber 2310 and the diffusion chamber 2340. This is because even if such plasma P and/or the processing gas G flows into the diffusion chamber 2340 and diffusion may occur, it is relatively concentrated in the central zone of the baffle 2130 due to the inertia of the flowing plasma P and/or the processing gas G. In this case, the temperature of the central zone A of the baffle 2130 may be excessively increased and its shape may be deformed. Additionally, the plasma P and/or the processing gas G may be concentrated in the central zone of the substrate W supported by the support unit 2120, thereby reducing the uniformity of processing the substrate W.

### SUMMARY

The present disclosure is directed to providing an apparatus capable of efficiently processing a substrate.

The present disclosure is also directed to providing a substrate processing apparatus capable of carrying out a uniform plasma treatment on a substrate.

Furthermore, the present disclosure is directed to providing a substrate processing apparatus capable of minimizing an excessive increase in temperature in a central zone of a baffle.

The problem to be solved by the present disclosure is not limited thereto, and other problems that are not mentioned will be clearly understood by those having an ordinary skill in art from the present specification and the accompanying drawings.

An exemplary embodiment of the present disclosure provides an apparatus for processing a substrate. A substrate processing apparatus comprises: a process processing unit for providing a processing space in which a substrate processing is performed; a plasma generation unit for generating plasma, wherein the plasma generation unit comprises: a plasma chamber having a plasma generation space; a gas supply unit for supplying a processing gas to the plasma generation space; a power application unit for generating plasma by exiting the processing gas in the plasma generation space; a diffusion chamber disposed below the plasma chamber and having a diffusion space for diffusing the plasma generated in the plasma generation space and/or the processing gas supplied to the plasma generation space to be uniformly delivered to the processing space, wherein at least one perforated diffusion plate may be disposed in the diffusion space.

In one embodiment, when viewed from above, the central zone of the diffusion plate is provided as a blocking plate and the perforations may be formed on the edge zone.

In one embodiment, when viewed form the top, the diffusion plate may have the perforations inclined down outwardly so that the processing gas and/or the plasma flowing through the perforations may flow from the central zone to the edge zone.

In one embodiment, the diffusion chamber may comprise: a connection part connected to a lower end of the plasma chamber; a diffusion unit extending from the connection part and having a larger diameter as it goes downward, wherein the diffusion plate may be disposed on the diffusion unit among the connection part and the diffusion unit.

In one embodiment, the connection part may have a diameter smaller than that of the diffusion unit and may have the same diameter as the plasma chamber.

In one embodiment, the diffusion plate may be made of a material including at least one of quartz, ceramic and aluminum.

In one embodiment, when viewed from above, the perforations may have a circle or slit shape.

In one embodiment, the process processing unit may comprise: a housing having the processing space; and a baffle disposed between the diffusion space and the processing space.

In one embodiment, when viewed from the cross section, the baffle may have a thicker thickness of central zone than the thickness of edge zone.

In one embodiment, the diffusion chamber may be provided with a material including quartz.

In an exemplary embodiment, the present disclosure is directed to providing a substrate processing apparatus capable of processing a substrate efficiently.

In one embodiment, the inner wall of the chamber may minimize the generation of impurities by reacting with the plasma.

In one embodiment, the longevity of plasma chamber may be extended.

In one embodiment, it is possible to minimize damage to the coating film covering the inner wall of the plasma chamber or separation from the inner wall of the plasma chamber.

The effects of the present disclosure are not limited thereto, and other effects that are not mentioned will be clearly understood by those having an ordinary skill in the art from the present specification and the accompanying drawings.

### BRIEF DESCRIPTION OF THE FIGURES

FIG. 1 is view showing a conventional plasma processing apparatus.

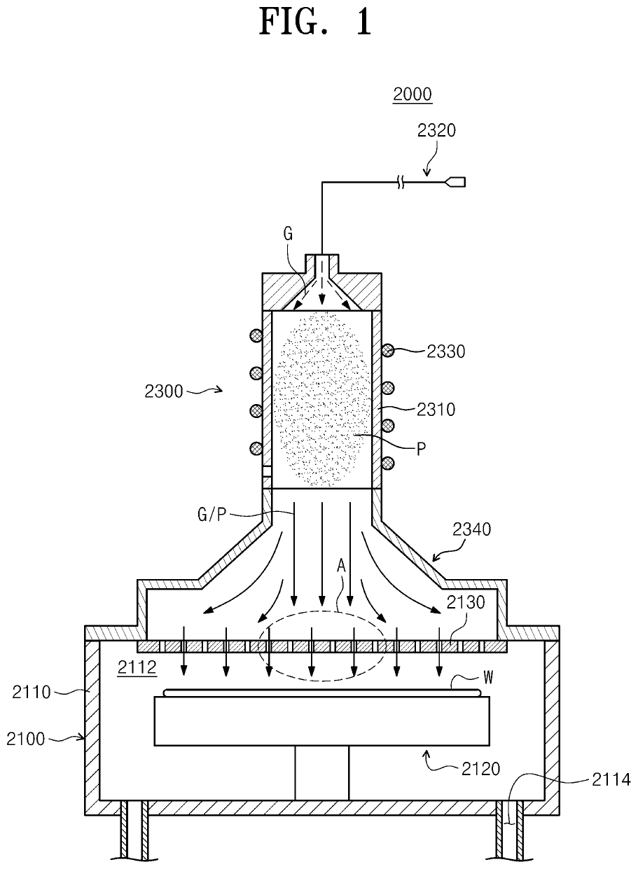

FIG. 2 is a schematic view showing a substrate processing apparatus of the present disclosure.

FIG. 3 is a view showing a substrate processing apparatus according to an embodiment of the present disclosure.

FIG. 4 is a view as viewed from the top of the diffusion plate of FIG. 3.

FIG. 5 is a view that a substrate processing apparatus of FIG. 3 treats a substrate.

FIG. 6 is graphs with two line: one line showing a temperature change of a central zone of baffle when a diffusion plate is provided to the diffusion chamber and the other line showing a temperature change of a central zone of baffle when a diffusion is not provided to the diffusion chamber.

FIG. 7 is a view showing a substrate processing apparatus according to another embodiment of the present disclosure.

FIG. 8 is a view showing a diffusion plate according to another embodiment of the present disclosure.

### DETAILED DESCRIPTION

Hereinafter, embodiments of the present disclosure will be described in more detail with reference to the accompanying drawings so that those with average knowledge in the art could easily carry out the present disclosure. The embodiments of the present disclosure may be modified in various forms, and the scope of the present disclosure should not be construed as being limited to the following embodiments. Additionally, in a preferred embodiment of the present disclosure, when it is deemed that a detailed description of known functions or configurations may unnecessarily obscure the subject matter of the present disclosure, the detailed description thereof will be omitted. Throughout the drawings, the same reference numerals are used to refer to the same or like parts.

Whenever appropriate, the terms “comprise” or “comprising” means that other components may be further included rather other components are excluded unless stated explicitly to the contrary herein. More specifically, the terms “comprise”, “have” or “include” etc. are intended to indicate that there is a feature, number, step, action, component, part, or combination thereof described on the specification. It is to be understood that the present disclosure does not exclude the possibility of the presence or the addition of one or more other features or numbers, steps, operations, components, parts or a combination thereof.

Singular expressions include plural expressions unless the context clearly indicates otherwise. Accordingly, the shapes, sizes, etc. of elements in the drawings may be exaggerated to make the description clear.

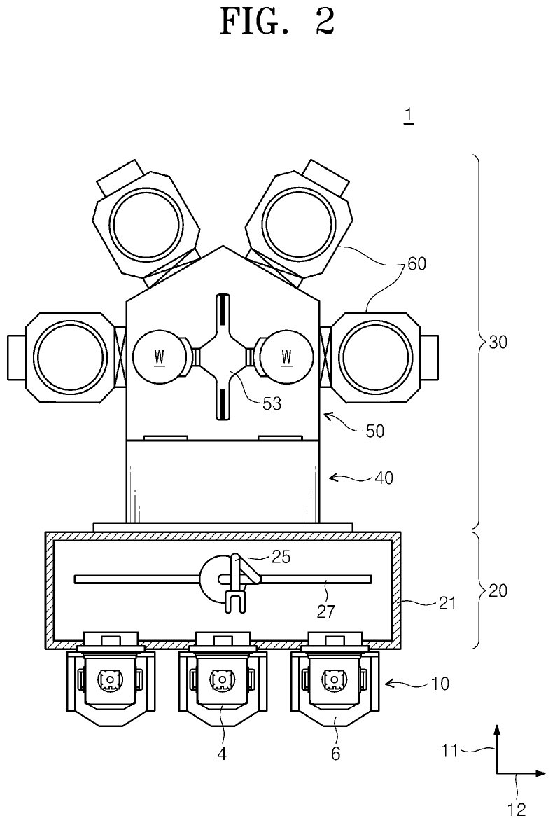

Embodiments of the present disclosure will be described in detail with reference to FIGS. 2 to 8.

FIG. 2 is a schematic view showing a substrate processing apparatus of the present disclosure. Referring to FIG. 2, the substrate processing apparatus 1 comprises an equipment front end module (EFEM) 20 and a processing module 30. The equipment front end module 20 and the processing module 30 are arranged in one direction.

The equipment front end module 20 comprises a load port 10 and a transfer frame 21. The load port 10 is disposed in the first direction 11 in front of the equipment front end module 20. The load port 10 has a plurality of supports 6. Each of the supports 6 is arranged in a line in the second direction 12, and a carrier 4 (for example, a cassette, FOUP or the like) for accommodating a substrate W to be provided for a process and a substrate W that has been processed is settled on the supports 6. The carrier 4 accommodates a substrate W to be provided for a process and a substrate W that has been processed. The transfer frame 21 is disposed between the load port 10 and the processing module 30. The transfer frame 21 comprises a first transfer robot 25 disposed therein and transferring the substrate W between the load port 10 and the processing module 30. The first transfer robot 25 transfers the substrate W between the carrier 4 and the processing module 30 moving along a transfer rail 27 provided in the second direction 12.

The processing module 30 comprises a load lock chamber 40, a transfer chamber 50, and a process chamber 60.

The load lock chamber 40 is disposed close to the transfer frame 21. For example, the load lock chamber 40 may be disposed between a transfer chamber 50 and the equipment front end module 20. The load lock chamber 40 provides a waiting space before the substrate W to be provided for the process is transferred to the process chamber 60 or before the substrate W that has been processed is transferred to the equipment front end module 20.

The transfer chamber 50 is disposed closed to the load lock chamber 40. When viewed from above, the transfer chamber 50 has a polygonal body. Referring to FIG. 2, the transfer chamber 50, when viewed from above, has pentagonal body. On the outside of the body, the load lock chamber 40 and a plurality of process chambers 60 are disposed along a circumference of the body. A passage (not shown) through which the substrate W enters and exits is formed on each side wall of the body, and the passage connects the transfer chamber 50, the load lock chamber 40, and the process chambers 60. Each passage is provided with a door (not shown) that opens and closes the passage. A second transfer robot 53 for transferring the substrate W between the load lock chamber 40 and the process chambers 60 are disposed in the inner space of the transfer chamber 50. The second transfer robot 53 transfers an unprocessed substrate W waiting in the load lock chamber 40 to the process chambers 60, or transfers a substrate W that has been processed to the load lock chamber 40. In order to provide the substrate W to a plurality of process chambers 60 in sequential order, the substrate W is transferred among the process chambers 60. As shown in FIG. 2, when the transfer chamber 50 has a pentagonal body, the load lock chamber 40 is disposed on one sidewall close to the equipment front end module 20 and the process chambers 60 are disposed on the other sidewalls in sequential order. The transfer chamber 50 may be provided in various shapes according to a required process module.

The process chambers 60 are disposed along the circumference of the transfer chamber 50. A process of the substrate W is carried out in each process chambers 60. The process chambers 60 process a substrate W received from the second transfer robot 53 and the second transfer robot 53 transfers the substrate W that has been processed in the process chambers 60. Each process performed on each of the process chambers 60 may be different from each other. In an exemplary embodiment, a substrate processing apparatus 1000 performing the plasma processing process in the process chambers 60 will be described in detail.

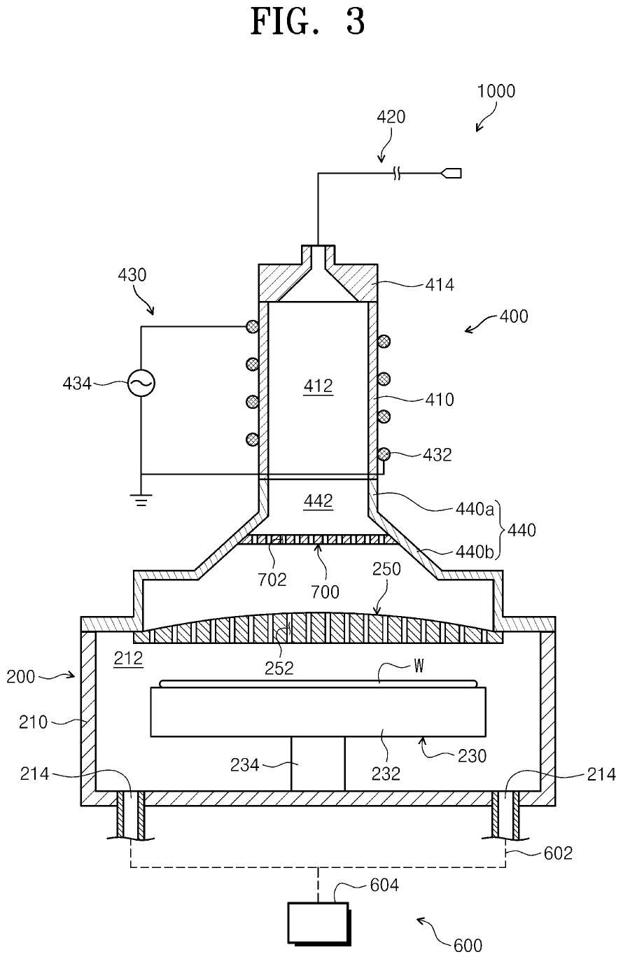

FIG. 3 is a view showing a substrate processing apparatus according to an embodiment of the present disclosure. For example, FIG. 3 may be a view showing a substrate processing apparatus performing a plasma processing process in the process chambers of FIG. 2. Referring to FIG. 3, the substrate processing apparatus 1000 performs a predetermined process on the substrate W using plasma. For example, a thin film on the substrate W may be removed by etching or ashing in the substrate processing apparatus 1000. The thin film may be various types of films such as a polysilicon film, a silicon oxide film, and a silicon nitride film. Additionally, the thin film may be a natural oxide film or a chemically generated oxide film.

The substrate processing apparatus 1000 has a process processing unit 200, a plasma generation unit 400, and an exhaust unit 600.

The process processing unit 200 provides a processing space 212 in which a substrate W is placed and processing on the substrate is performed. The plasma generation unit 400 generates plasma by discharging the processing gas, and supplies the plasma to the processing space 212 of the process processing unit 200. The exhaust unit 600 exhausts a processing gas remaining in the process processing unit 200 and/or byproducts of reaction generated during a substrate processing process to the outside and maintains the pressure in the process processing unit 200 at a set pressure.

The process processing unit 200 may include a housing 210, a support unit 230 and a baffle 250.

A processing space 212 for performing a substrate processing process may be provided inside the housing 210. The upper portion of the housing 210 may be opened, and an opening (not shown) may be formed on a sidewall. The substrate W enters and exits the housing 210 through the opening. The opening may be opened or closed by an opening member such as a door (not shown). Additionally, an exhaust hole 214 is formed on the bottom surface of the housing 210. Processing gases and/or byproducts in the processing space 212 may be exhausted to the outside of the processing space 212 through the exhaust hole 214. The exhaust hole 214 may be connected to components included in the exhaust unit 600, which are described below.

The support unit 230 supports the substrate W in the processing space 212. The support unit 230 may include a support plate 232 and a support shaft 234. The support plate 232 may support the substrate W in the processing space 212. The support plate 232 may be supported by the support shaft 234. The support plate 232 is connected to an external power source and may generate static electricity by the applied power. The electrostatic force of the generated static electricity may fix the substrate W to the support unit 230.

The support shaft 234 may move the object. For example, the support shaft 234 may move the substrate W in the vertical direction. For example, the support shaft 234 may be coupled to the support plate 232 and move the substrate W by raising and lowering the support plate 232.

The baffle 250 may uniformly supply the plasma P and/or processing gas G flowing into the processing space 212 to the substrate W. The baffle 250 is disposed over the support unit 230 so as to face the support unit 230. The baffle 250 may be disposed between the support unit 230 and the plasma generation unit 400. That is, the baffle 250 may be disposed between the processing space 212 and the diffusion space 442 of the diffusion chamber 440, which is described below. Also, the baffle 250 may be coupled to the diffusion chamber 440. Additionally, the baffle 250 may be detachably coupled to the diffusion chamber 440. Plasma generated by the plasma generation unit 400 may pass through a plurality of holes 252 formed on the baffle 250. The holes 252 formed on the baffle 250 are provided as through holes provided from the top to the bottom of the baffle 250, and may be uniformly formed on each region of the baffle 250.

When viewed from the front cross-section, the baffle 250 may have a thicker thickness at the central zone thereof than at the edge zone thereof. Additionally, the upper surface of the baffle 250 may have a curved shape. For example, the upper surface of the baffle 250 may have a rounded shape to be convex upward. Furthermore, the lower surface of the baffle 250 may have a flat shape. Since the upper surface of the baffle 250 has a convex shape, the plasma P and/or the processing gas G introduced into the diffusion chamber 440 which is described below may be uniformly introduced into the processing space 212.

The plasma generation unit 400 may be disposed over the housing 210. The plasma generation unit 400 may generate plasma by discharging a processing gas, and may supply the generated plasma to the processing space 212. The plasma generation unit 400 may include a plasma chamber 410, a gas supply unit 420, a power application unit 430, and a diffusion chamber 440.

The plasma chamber 410 may have an open upper portion and an open lower portion. The plasma chamber 410 may have a container shape with the upper and lower portions opened. The plasma chamber 410 may have a cylindrical shape with the upper and lower portions opened. The plasma chamber 410 may have a plasma generation space 412. Additionally, the plasma chamber 410 may be made of a material including aluminum oxide (Al2O3). The upper portion of the plasma chamber 410 may be covered by a gas supply port 414. The gas supply port 414 may be connected to the gas supply unit 420. The processing gas may be supplied to the plasma generation space 412 through the gas supply port 414. The processing gas G supplied to the plasma generation space 412 may flow into the processing space 212 through the baffle 250.

The gas supply unit 420 may supply the processing gas G. The gas supply unit 420 may be connected to the gas supply port 414. The processing gas G supplied by the gas supply unit 420 may include fluorine and/or hydrogen

The power application unit 430 applies high-frequency power to the plasma generation space 412. The power application unit 430 may be a plasma source that generates plasma by exciting a processing gas in the plasma generation space 412. The power application unit 430 may include an antenna 432 and a power source 434.

The antenna 432 may be an inductively coupled plasma (ICP) antenna. The antenna 432 may be provided in a coil shape. The antenna 432 may be wound around the plasma chamber 410 outside the plasma chamber 410 a plurality of times. The antenna 432 may be wound around the plasma chamber 410 a plurality of times in a spiral shape outside the plasma chamber 410. The antenna 432 may be wound around the plasma chamber 410 in an area corresponding to the plasma generation space 412. One end of the antenna 432 may be provided at a height corresponding to the upper portion of the plasma chamber 410 when viewed from the front of the plasma chamber 410. The other end of the antenna 432 may be provided at a height corresponding to the lower portion of the plasma chamber 410 when viewed from the front of the plasma chamber 410.

The power source 434 may apply power to the antenna 432. The power source 434 may apply a high-frequency alternating current to the antenna 432. The high-frequency alternating current applied to the antenna 432 may induce electric field in the plasma generation space 412. The process gas supplied into the plasma generation space 412 may be converted into a plasma state by obtaining energy required for ionization from the induced electric field. Additionally, the power source 434 may be connected to one end of the antenna 432. The power source 434 may be connected to one end of the antenna 432 provided at a height corresponding to the upper portion of the plasma chamber 410. Furthermore, the other end of the antenna 432 may be connect to ground. The other end of the antenna 432 provided at a height corresponding to the lower portion of the plasma chamber 410 may be connect to ground. But the present disclosure is not limited thereto, and the power source 434 may be connected to the other end of the antenna 432 and one end of the antenna 432 may be connect to ground.

The diffusion chamber 440 may diffuse the plasma P generated in the plasma chamber 410. The diffusion chamber 440 may have diffusion space 442 so that the plasma P generated in the plasma generation space 412 and/or the process gas G introduced into the plasma generation space 412 may be uniformly delivered to the processing space 212. The plasma P generated in the plasma generation space 412 may be diffused while passing through the diffusion space 442. The plasma P introduced into the diffusion space 442 may flow into the processing space 412 through the baffle 250. Additionally, the diffusion chamber 440 may be made of a material including quartz.

The diffusion chamber 440 may be disposed below the plasma chamber 410. The diffusion chamber 440 may be disposed above the housing 210. That is, the diffusion chamber 440 may be disposed between the plasma chamber 410 and the housing 210. The diffusion chamber 440 may have a shape in which upper and lower portions are open. The diffusion chamber 440 may have a shape similar to a reversed funnel. The diffusion chamber 440 may comprise a connection part 440a and a diffusion part 440b. The connection part 440a may be connected to the lower end of the plasma chamber 410. The connection part 440a may have the same diameter as or similar to the plasma chamber 410 when viewed from above. The connection part 440a may have a shape having a constant diameter as it goes from the top to the bottom. The diffusion part 440b may extend downward from the connection part 440a. The diffusion part 440b may have a larger diameter as it goes downward. Accordingly, the connection part 440a may have a diameter smaller than a diameter of the diffusion part 440b when viewed from above.

The exhaust unit 600 may exhaust processing gases and impurities inside the process processing unit 200 to the outside. The exhaust unit 600 may exhaust impurities generated during the processing of the substrate W to the outside of the substrate processing apparatus 1000. The exhaust unit 600 may exhaust the process gas supplied into the processing space 212 to the outside. The exhaust unit 600 may comprise an exhaust line 602 and a pressure reducing member 604. The exhaust line 602 may be connected to the exhaust hole 214 formed at the bottom surface of the housing 210. Further, the exhaust line 602 may be connected with a pressure reducing member 604 that provides a reduced pressure. Accordingly, the pressure reducing member 604 may provide depressurization to the processing space 212. The pressure reducing member 604 may be a pump. The pressure reducing member 604 may exhaust plasma and impurities remaining in the processing space 212 to the outside of the housing 210. Additionally, the pressure reducing member 604 may provide depressurization to maintain the pressure in the processing space 212 at a preset pressure.

A diffusion plate 700 may minimize the delivery or flow of the plasma P and/or the process gas G introduced into the diffusion space 442 to the central zone of the baffle 250. The diffusion plate 700 may minimize the plasma P and/or the process gas G introduced into the diffusion space 442 from colliding with the central zone of the baffle 250. The diffusion plate 700 may be provided in the diffusion space 442 of the diffusion chamber 440. The diffusion plate 700 may be disposed on the diffusion part 440b. The diffusion plate 700 is disposed in the diffusion space 442 formed by the diffusion part 440b.

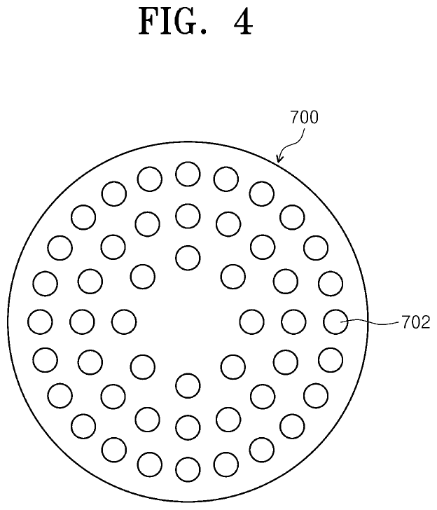

FIG. 4 is a view when viewed from the top of the diffusion plate of FIG. 3. Referring to FIG. 4, the diffusion plate 700 may have a disk shape. At least one perforation hole 702 may be formed on the diffusion plate 700. A plurality of perforation holes 702 may be formed on the diffusion plate 700. The perforation holes 702 formed on the diffusion plate 700 may be formed to extend from the top surface of the diffusion plate 700 to the bottom surface of the diffusion plate 700. That is, the perforation holes 702 formed on the diffusion plate 700 may be formed through the top and bottom surfaces of the diffusion plate 700. When viewed from above, the central zone of the diffusion plate 700 where the perforation holes 702 are not formed, may be provided as a blocking plate. Further, when viewed from above, the perforation hole 702 are formed at the edge zone of the diffusion plate 700. The perforation holes 702 may have a circular shape in cross-section. Additionally, the diffusion plate 700 may be made of a material including at least one of quartz, ceramic, and aluminum. For example, the diffusion plate 700 may be made of a material including quartz. Additionally, the diffusion plate 700 may be made of a material including ceramic. And, the diffusion plate 700 may be made of a material including aluminum.

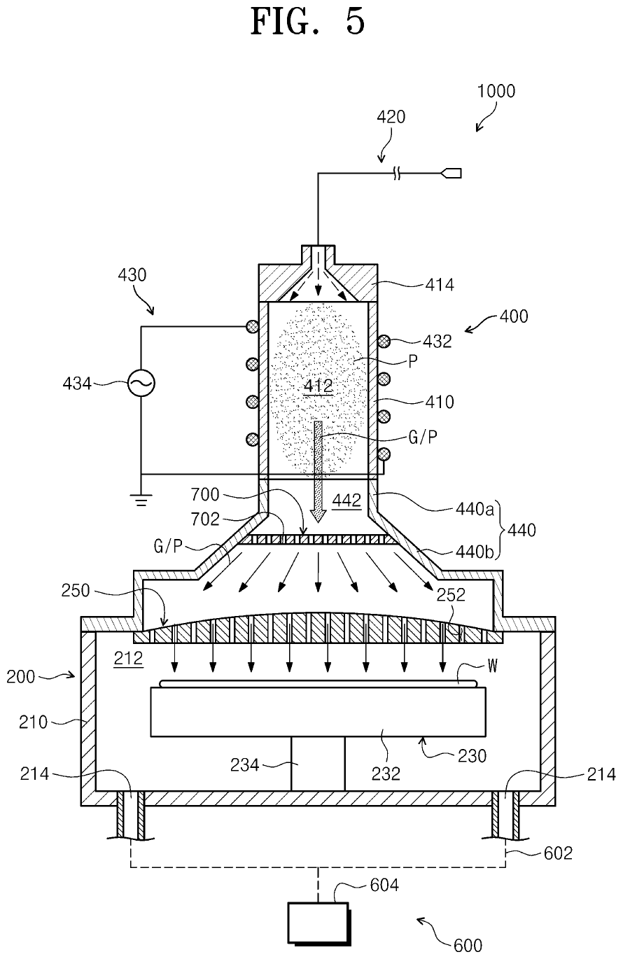

FIG. 5 is a view that a substrate processing apparatus of FIG. 3 treats a substrate. Referring to FIG. 5, in the plasma generation space 412, the process gas G supplied by the gas supply unit 420 may be excited into a plasma P state. The plasma P generated in the plasma generation space 412 and/or the process gas G supplied to the plasma generation space 412 may be introduced into the processing space 212 through the plasma generation space 412, the diffusion space 442, and the baffle 250. At this time, the central zone of the diffusion plate 700 disposed in the diffusion space 442 serves as a blocking plate so that it is possible to minimize the concentration of the process gas G and/or plasma P transmitted to the central zone of the baffle 250. Additionally, the flow rate of the plasma P and/or the process gas G is reduced by the diffusion plate 700, so that the diffusion of the process gas G and/or the plasma P in the diffusion space 442 is efficiently reduced. Accordingly, the process gas G and/or plasma P introduced into the processing space 212 can be more uniformly delivered to the substrate W supported by the support unit 230.

Additionally, the blocking plate according to an embodiment of the present disclosure is provided on the diffusion part 440b among the connection part 440a and the diffusion part 440b of the diffusion chamber 440. The plasma P and/or the processing gas G introduced into the diffusion space 442 formed by the connection part 440a flows into the diffusion space 442 formed by the diffusion part 440b. In this case, the volume of the diffusion space 442 formed by the diffusion part 440b is larger than the volume of the diffusion space 442 formed by the connection part 440a. Accordingly, the flow rate of the plasma P and/or the processing gas G introduced into the diffusion space 442 formed by the diffusion part 440b is further slowed. Accordingly, the increase in temperature of the diffusion plate 700 due to collision with the plasma P and/or the processing gas G may be more efficiently reduced. Plasma P and/or processing gas G flowing through the perforation holes 702 formed on the diffusion plate 700 may be efficiently diffused in the diffusion space 442 while the flow rate thereof is reduced.

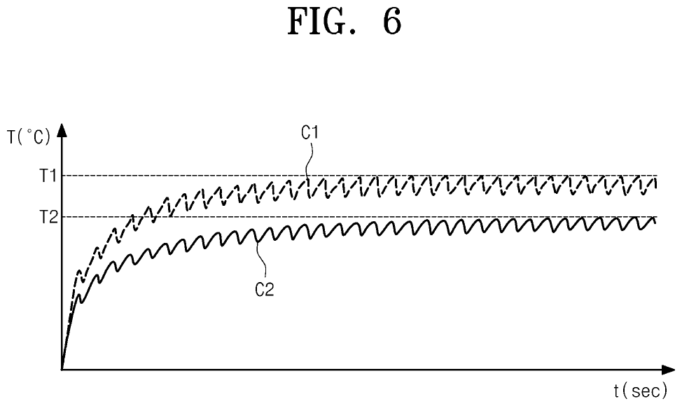

FIG. 6 is a graph showing a temperature change in a baffle central zone when a diffusion plate is provided in the diffusion chamber and a temperature change in a baffle central zone when a diffusion plate is not provided in the diffusion chamber. Referring to FIG. 6, the first temperature change line C1 shows a temperature change in the central zone of the baffle when the diffusion plate 700 is not provided in the diffusion chamber 440.The second temperature change line C2 shows a temperature change in the central zone of the baffle in the case the diffusion plate 700 is provided in the diffusion chamber 440. As can be seen in FIG. 6, when the diffusion plate 700 is not provided in the diffusion chamber 440, the temperature of the central zone of the baffle 250 increases to the first temperature T1. When the plate 700 is provided, the temperature of the central zone of the baffle 250 may increase to the second temperature T2 which is lower than the first temperature T1. That is, the diffusion plate 700 according to an embodiment of the present disclosure is provided in the diffusion chamber 440 to minimize an excessive increase in temperature in the central zone of the baffle 250. Accordingly, thermal deformation of the baffle 250 may be minimized. Additionally, the plasma P and/or the processing gas G may be more uniformly delivered to the processing space 212.

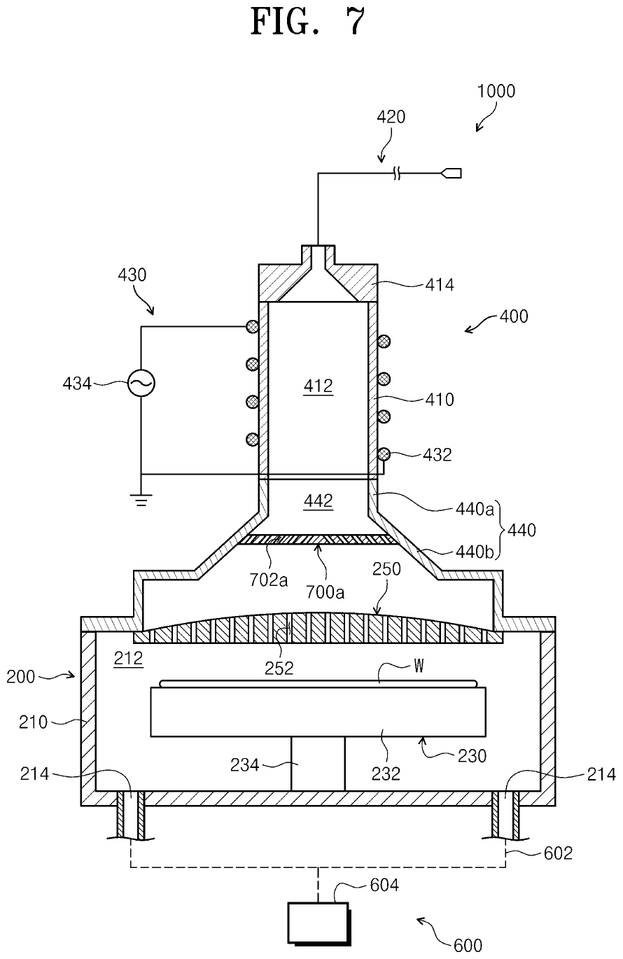

FIG. 7 is a view showing a substrate processing apparatus according to another embodiment of the present disclosure. Referring to FIG. 7, a perforation hole 702a formed on the diffusion plate 700a may be slightly inclined. For example, the perforation hole 702a may be down and outwardly inclined on the plate 700a so that the processing gas G and/or plasma P flowing through the perforated hole 702a, when viewed from above, flows from the center zone of the diffusion plate 700a to the edge zone of the diffusion plate 700a. In this case, the plasma P and/or the processing gas G in the diffusion chamber 440 may be diffused more efficiently.

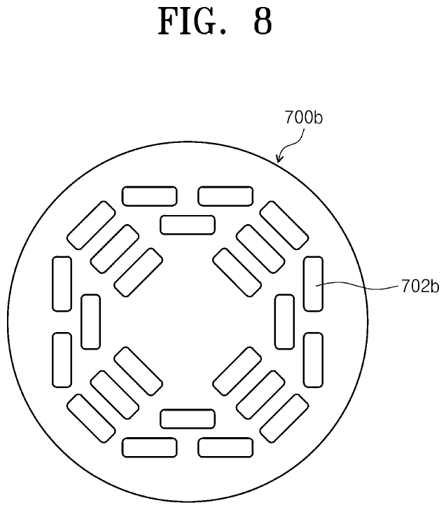

In the example hereinabove, the perforation hole 702 formed on the diffusion plate 700 has been described as having a circular shape, but is not limited thereto. For example, as shown in FIG. 8, the perforation hole 702b formed on the diffusion plate 700b may have a slit shape. But the present disclosure is not limited thereto, and the shape of the perforation formed on the diffusion plate may have various modifications.

The embodiments herein may be variously applied to a substrate processing apparatus using plasma. For example, the embodiments herein may be applied in the same or similar manner to various apparatus that perform an ashing process, a deposition process, an etching process, or a clean process using plasma.

The detailed descriptions herein are illustrative of the present disclosure. Additionally, the descriptions herein show and describe preferred embodiments of the present disclosure, and the present disclosure can be used in various other combinations, modifications and environments. That is, changes or modifications are possible within the scope of the concept of the invention disclosed in the present specification, the scope equivalent to the disclosed contents, and/or within the skill or knowledge of the art. The embodiments herein describe the best process and method for implementing the technical idea of the present invention, and various changes required in the specific application fields and uses of the present disclosure are also available. Accordingly, the detailed descriptions of the disclosure are not intended to limit the invention to the disclosed embodiments. Additionally, the scope of claims hereinafter should be construed as including other embodiments
A process processing unit: 200
A housing: 210
A processing space: 212
A baffle: 250
A plasma generation unit: 400
A plasma chamber: 410
A plasma generation space: 412
A diffusion chamber:440
A diffusion space: 442
A diffusion plate: 700
Perforation hole: 702

What is claimed is:

1. An apparatus for processing a substrate, the apparatus comprising:
a process processing unit for providing a processing space in which a substrate processing is performed; and
a plasma generation unit for generating plasma, wherein the plasma generation unit comprises:
a plasma chamber having a plasma generation space;
a gas supply unit for supplying a processing gas to the plasma generation space;
a power application unit for generating plasma by exiting the processing gas in the plasma generation space;
a diffusion chamber disposed below the plasma chamber and having a diffusion space for diffusing the plasma generated in the plasma generation space and/or the processing gas supplied to the plasma generation space to be uniformly delivered to the processing space,
wherein a diffusion plate provided with at least one perforation holes is disposed in the diffusion space.

2. The apparatus of claim 1, wherein the diffusion plate, when viewed from above, the central zone of the diffusion plate is provided as a blocking plate and the at least one perforation holes are formed on the edge zone of the diffusion plate.

3. The apparatus of claim 2, wherein the at least one perforation holes, when viewed from above, are inclined down outwardly so that the processing gas and/or the plasma flowing through the perforations flow from the central zone to the edge zone.

4. The apparatus of claim 1, wherein the diffusion chamber comprises:
a connection part connected to a lower end of the plasma chamber;
a diffusion part extending from the connection part and having a larger diameter as it goes downward, wherein the diffusion plate is disposed at the diffusion part.

5. The apparatus of claim 4, wherein the connection part has a diameter smaller than that of the diffusion part and has the same diameter as the plasma chamber.

6. The apparatus of claim 1, wherein the diffusion plate is made of a material including at least one of quartz, ceramic and aluminum.

7. The apparatus of claim 1, wherein the at least one perforation holes, when viewed from above, have a circle or slit shape.

8. The apparatus of claim 1, wherein the process processing unit comprises: a housing having the processing space; and a baffle disposed between the diffusion space and the processing space.

9. The apparatus of claim 8, wherein the baffle, when viewed from the cross section, has a thicker thickness at the central zone than at the edge zone.

10. The apparatus of claim 1, wherein the diffusion chamber is provided with a material including quartz.
